(19) United States
(12) Patent Application Publication
(10) Pub. No.: US 2017/0229315 A1
(43) Pub. Date: Aug. 10, 2017

(54) INTEGRATED LAYER ETCH SYSTEM WITH MULTIPLE TYPE CHAMBERS

(71) Applicant: Applied Materials, Inc., Santa Clara, CA (US)

(72) Inventors: Ying ZHANG, Santa Clara, CA (US); Qingjun ZHOU, San Jose, CA (US); Jonathan Sungehul KIM, Danville, CA (US)

(21) Appl. No.: 15/415,348

(22) Filed: Jan. 25, 2017

Related U.S. Application Data
(60) Provisional application No. 62/292,022, filed on Feb. 5, 2016.

(51) Int. Cl. H01L 21/3105; H01L 21/311; H01L 21/67

(52) U.S. Cl. CPC H01L 21/3105; H01L 21/67196; H01L 21/67207; H01L 21/67167; H01L 21/31116

(57) ABSTRACT

Embodiments described herein generally relate to a substrate processing system, such as an etch processing system. In one embodiment, a substrate processing system is disclosed herein. The substrate processing system includes a transfer chamber and a plurality of process chambers coupled to the transfer chamber. The plurality of process chambers includes a first process chamber, a second process chamber, and a third process chamber. The first process chamber is configured to directionally modify a surface of a film stack formed on the substrate. The second process chamber is configured to deposit an etchant on the surface of the film stack. The third process chamber is configured to expose the film stack to a high-temperature sublimation process.

### CROSS-REFERENCE TO RELATED APPLICATION

This application claims priority from U.S. Provisional Application Ser. No. 62/292,022, filed Feb. 5, 2016, which is hereby incorporated by reference in its entirety.

### BACKGROUND

Field

Embodiments described herein relate to an etch system for substrate processing, and more specifically to an integrated layer etch system with multiple type chambers.

Description of the Related Art

Reliably producing sub-half micron and smaller features is one of the key technology challenges for next generation very large scale integration (VLSI) and ultra large-scale integration (ULSI) of semiconductor devices. However, as the limits of circuit technology are pushed, the shrinking dimensions of VLSI and ULSI technology have placed additional demands on processing capabilities. Reliable formation of gate structures on the substrate is important to VLSI and ULSI success and to the continued effort to increase circuit density and quality of individual substrates and die.

As circuit densities increase for next generation devices, the widths of interconnects, such as vias, trenches, contacts, gate structures and other features, as well as the dielectric materials therebetween, decrease to 45 nm and 32 nm dimensions, whereas the thickness of the dielectric layers remain substantially constant, with the result of increasing the aspect ratios of the features. In order to enable fabrication of next generation devices and structures, three dimensional (3D) stacking of semiconductor chips is often utilized to improve performance of the transistors. By arranging transistors in three dimensions instead of conventional two dimensions, multiple transistors may be placed in the integrated circuits (ICs) very close to each other. Three dimensional (3D) stacking of semiconductor chips reduces wire lengths and keeps wiring delay low. In manufacturing three dimensional (3D) stacking of semiconductor chips, stair-like structures are often utilized to allow multiple interconnection structures to be disposed thereon, forming high-density of vertical transistor devices.

Thus, there is a need for improved methods for processing substrates to continue to decrease the manufacturing costs, memory cell size, and power consumption of the integrated circuits.

### SUMMARY

Embodiments described herein generally relate to a substrate processing system, such as an etch processing system. In one embodiment, a substrate processing system is disclosed that includes a transfer chamber having a plurality of process chambers coupled thereto. The plurality of process chambers includes a first process chamber, a second process chamber, and a third process chamber. The first process chamber is configured to directionally modify a surface of a film stack formed on a substrate processed within the first process chamber. The second process chamber is configured to deposit an etchant on the surface of the film stack. The third process chamber is configured to expose the film stack to a high-temperature sublimation process.

In another embodiment, a method for processing a substrate is disclosed herein. The method includes directionally modifying exposed layers of a film stack deposited on a surface of the substrate, selectively depositing etchants on a modified surface of the exposed layers, and exposing the substrate to a high-temperature sublimation process.

In another embodiment, another substrate processing system is disclosed herein. The substrate processing system includes a transfer chamber, a plurality of process chambers coupled to the transfer chamber, and a substrate handler. The plurality of process chambers includes a first process chamber, a second process chamber, a third process chamber, and a fourth processing chamber. The first process chamber is configured to directionally modify a surface of a film stack formed on a substrate processed within the first processing chamber. The second process chamber is configured to deposit an etchant on the surface of the film stack. The third process chamber is configured to expose the film stack to a high-temperature sublimation process. The fourth process chamber is configured to etch the film stack. The substrate handler is disposed in the transfer chamber and configured to transfer the substrate among the process chambers.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a cross sectional view of an illustrative processing chamber suitable for a silicon material removal process, according to one embodiment.

FIG. 2 is a sectional view of one example of a processing chamber suitable for performing a patterning process, according to one embodiment.

FIG. 3 depicts a plan view of a semiconductor processing system, according to one embodiment.

FIG. 4 depicts a plan view of a semiconductor processing system, according to another embodiment.

FIG. 5 is a flow diagram that illustrates one embodiment of a method for processing a substrate, according to one embodiment.

FIGS. 6A-6E illustrate cross-sectional views of the substrate at different stages of the method of FIG. 5, according to one embodiment.

For clarity, identical reference numerals have been used, where applicable, to designate identical elements that are common between figures. Additionally, elements of one embodiment may be advantageously adapted for utilization in other embodiments described herein.

### DETAILED DESCRIPTION

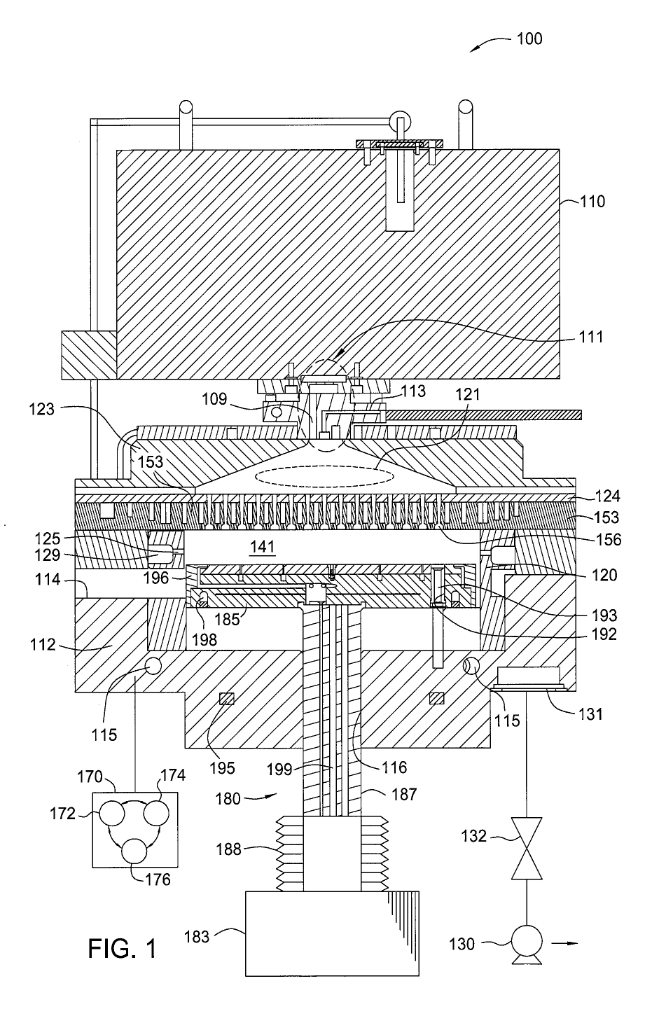

FIG. 1 illustrates a processing chamber 100, according to one example. The processing chamber 100 may be configured to remove materials from a material layer disposed on a surface of a substrate. The processing chamber 100 is particularly useful for performing a plasma assisted dry etch process.

The processing chamber 100 includes a chamber body 112 defining a processing region 141. A lid assembly 123 is disposed at an upper end of the chamber body 112 and bounds the processing region 141. A support assembly 180 is disposed below the lid assembly 123, at least partially within the chamber body 112.

The chamber body 112 includes a slit valve opening 114 formed in a sidewall thereof to provide access to the processing region 141 of the processing chamber 100. The slit valve opening 114 is selectively opened and closed by a door (not shown) to allow access to the processing region 141 of the chamber body 112 by a wafer handling robot (also not shown).

In one or more implementations, the chamber body 112 includes a channel 115 formed therein for flowing a heat transfer fluid therethrough. The chamber body 112 can further include a liner 120 that surrounds the support assembly 180. The liner 120 is removable for servicing and cleaning. In one or more embodiments, the liner 120 includes one or more apertures 125 and a pumping channel 129 formed therein that is in fluid communication with a vacuum system. The apertures 125 provide a flow path for gases into the pumping channel 129, which provides an egress for the gases within the processing chamber 100.

The vacuum system can include a vacuum pump 130 and a throttle valve 132 to regulate flow of gases through the processing chamber 100. The vacuum pump 130 is coupled to a vacuum port 131 disposed in the chamber body 112 which is in fluid communication with the pumping channel 129 formed within the liner 120.

A remote plasma system 110 may process a halogen containing precursor, for example fluorine-containing precursor. The halogen containing precursor then travels through a gas inlet assembly 111. Two distinct gas supply channels (a first channel 109 and a second channel 113) are present within the gas inlet assembly 111. In one example, the first channel 109 carries a gas that passes through the remote plasma system 110 (RPS), while the second channel 113 bypasses the remote plasma system 110. The lid assembly 123 and a showerhead 153 having a plurality of through holes 156 are separated by an insulating ring 124, which allows an AC potential to be applied to the lid assembly 123 relative to the showerhead 153. The AC potential between the lid assembly 123 and the showerhead 153 may be sufficient to strike a plasma in a chamber plasma region 121 defined between the lid assembly 123 and the showerhead 153.

The support assembly 180 may include a support member 185 configured to support a substrate (not shown in FIG. 1) for processing within the chamber body 112. The support member 185 can be coupled to a lift mechanism 183 through a shaft 187 which extends through a centrally-located opening 116 formed in a bottom surface of the chamber body 112. The lift mechanism 183 can be flexibly sealed to the chamber body 112 by a bellows 188 that prevents vacuum leakage from around the shaft 187. The support assembly 180 can further include an edge ring 196 disposed about the support member 185.

The support member 185 may include bores 192 formed therethrough to accommodate lift pins 193, one of which is shown in FIG. 1. The lift pin 193 is moveable within its respective bore 192 when displaced by a movable annular lift ring 195 disposed within the chamber body 112.

The temperature of the support assembly 180 can be controlled by a fluid circulated through a fluid channel 198 embedded in the body of the support member 185. In one or more implementations, the fluid channel 198 is in fluid communication with a heat transfer conduit 199 disposed through the shaft 187 of the support assembly 180. The fluid channel 198 is positioned about the support member 185 to provide a uniform heat transfer from the heat transfer conduit 199 to the substrate receiving surface of the support member 185. The fluid channel 198 and heat transfer conduit 199 can flow heat transfer fluids to either heat or cool the support member 185, as desired.

A controller 170 is coupled to the processing chamber 100 to control operation of the processing chamber 100. The controller 170 includes a central processing unit (CPU) 172, a memory 174, and a support circuit 176 utilized to control the process sequence and regulate the gas flows from the gas panel 178. The CPU 172 may be any form of general purpose computer processor that may be used in an industrial setting. The software routines can be stored in the memory 174, such as random access memory, read only memory, floppy, or hard disk drive, or other form of digital storage. The support circuit 176 is conventionally coupled to the CPU 172 and may include cache, clock circuits, input/output systems, power supplies, and the like. Bi-directional communications between the controller 170 and the various components of the processing chamber 100 are handled through numerous signal cables.

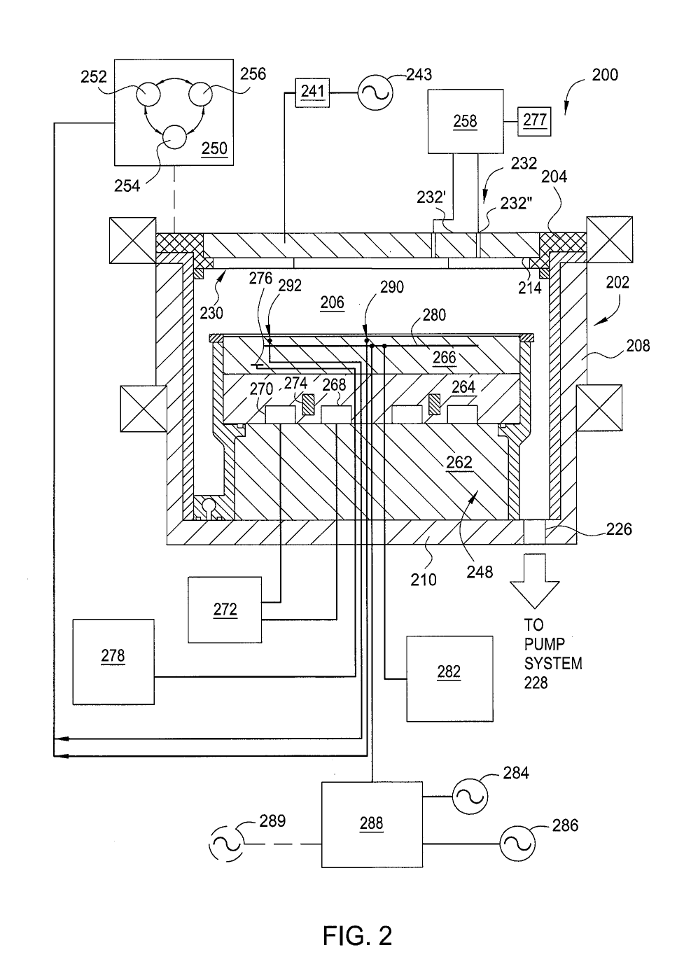

FIG. 2 illustrates a processing chamber 200, according to one example. The processing chamber 200 includes a chamber body 202 and a lid 204 which enclose an interior volume 206. The chamber body 202 generally includes sidewalls 208 and a bottom 210. A substrate support pedestal access port (not shown) may be defined in a sidewall 208 and a selectively sealed by a slit valve to facilitate entry and egress of a substrate 201 from the processing chamber 200. An exhaust port 226 is defined in the chamber body 202 and couples the interior volume 206 to a pump system 228.

A gas panel 258 is coupled to the processing chamber 200 to provide process and/or cleaning gases to the interior volume 206. In the example depicted in FIG. 2, inlet ports 232′, 232″ are provided in the lid 204 to allow gases to be delivered from the gas panel 258 to the interior volume 206 of the processing chamber 200.

A showerhead assembly 230 is coupled to an interior surface 214 of the lid 204. The showerhead assembly 230 includes a plurality of apertures that allow the gases flowing through the showerhead assembly 230 from the inlet ports 232′, 232″ into the interior volume 206 of the processing chamber 200 in a predefined distribution across the surface of the substrate 201 being processed in the processing chamber 200.

A remote plasma source 277 may be optionally coupled to the gas panel 258 to facilitate dissociating gas mixture from a remote plasma prior to entering into the interior volume 206 for processing. An RF source power 243 is coupled through a matching network 241 to the showerhead assembly 230.

The substrate support pedestal assembly 248 is disposed in the interior volume 206 of the processing chamber 200 below the showerhead assembly 230. The substrate support pedestal assembly 248 supports the substrate 201 during processing. The substrate support pedestal assembly 248 generally includes a plurality of lift pins (not shown) disposed therethrough that are configured to lift the substrate 201 from the substrate support pedestal assembly 248 and facilitate exchange of the substrate 201 with a robot (not shown) in a conventional manner.

In one implementation, the substrate support pedestal assembly 248 includes a mounting plate 262, a base 264 and an electrostatic chuck 266. The mounting plate 262 is coupled to the bottom 210 of the chamber body 202 includes passages for routing utilities to the base 264 and the electrostatic chuck 266. The electrostatic chuck 266 comprises at least one clamping electrode 280 for retaining the substrate 201 below showerhead assembly 230. The electrostatic chuck 266 is driven by a chucking power source 282 to develop an electrostatic force that holds the substrate 201 to the chuck surface, as is conventionally known. Alternatively, the substrate 201 may be retained to the substrate support pedestal assembly 248 by clamping, vacuum, or gravity.

At least one of the base 264 or electrostatic chuck 266 may include at least one optional embedded heater 276, at least one optional embedded isolator 274 and a plurality of conduits 268, 270 to control the lateral temperature profile of the substrate support pedestal assembly 248. The conduits 268, 270 are fluidly coupled to a fluid source 272 that circulates a temperature regulating fluid therethrough. The heater 276 is regulated by a power source 278. The conduits 268, 270 and heater 276 are utilized to control the temperature of the base 264, thereby heating and/or cooling the electrostatic chuck 266. The temperature of the electrostatic chuck 266 and the base 264 may be monitored using a plurality of temperature sensors 290, 292.

In one implementation, the substrate support pedestal assembly 248 is configured as a cathode and includes an electrode 280 that is coupled to a plurality of RF power bias sources 284, 286. The RF bias power sources 284, 286 are coupled to the electrode 280 disposed in the substrate support pedestal assembly 248 and another electrode through a matching circuit 288. An additional bias power source 289 may be coupled to the electrode 280 to control the characteristics of the plasma. The RF bias power excites and sustains a plasma discharge formed from the gases disposed in the processing region of the chamber body 202.

A controller 250 is coupled to the processing chamber 200 to control operation of the processing chamber 200. The controller 250 includes a central processing unit (CPU) 252, a memory 254, and a support circuit 256 utilized to control the process sequence and regulate the gas flows from the gas panel 258. The CPU 252 may be any form of general purpose computer processor that may be used in an industrial setting. The software routines can be stored in the memory 254, such as random access memory, read only memory, floppy, or hard disk drive, or other form of digital storage. The support circuit 256 is conventionally coupled to the CPU 252 and may include cache, clock circuits, input/output systems, power supplies, and the like. Bi-directional communications between the controller 250 and the various components of the processing chamber 200 are handled through numerous signal cables.

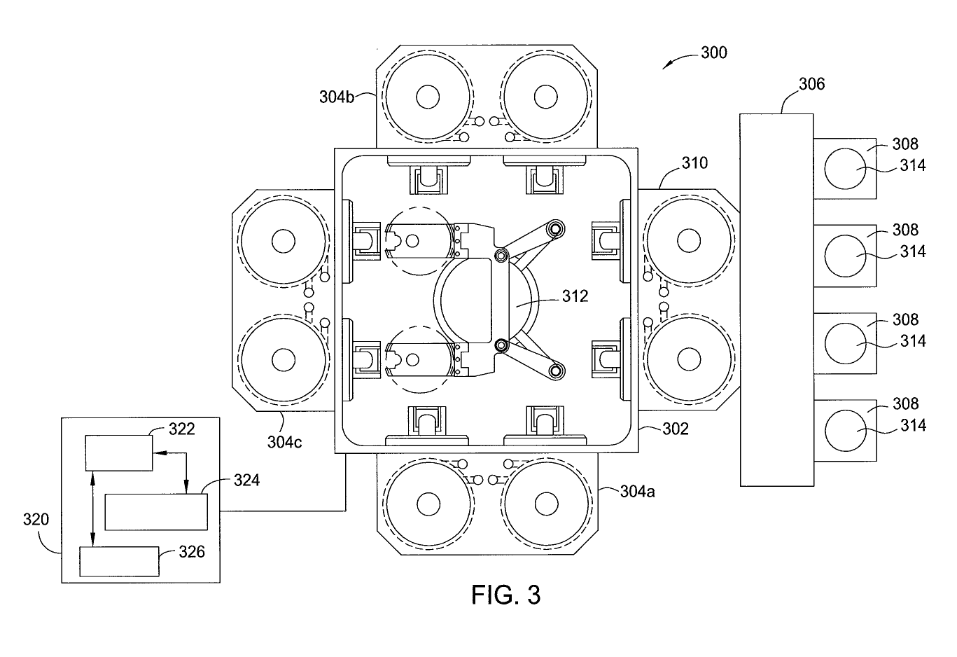

FIG. 3 illustrates a semiconductor processing system 300 on which the methods described herein may be practiced. One processing system that may be adapted to benefit from the invention is a 300 mm Producer™ processing system, commercially available from Applied Materials, Inc., of Santa Clara, Calif. The processing system 300 may include a transfer chamber 302 and a plurality of processing chambers 304a-304c coupled to the transfer chamber 302. The processing system may further include a front platform 306, front opening unified pods (FOUPs) 308, a loadlock chamber 310 and substrate handler 312.

The front platform 306 is where substrate cassettes 314 included in the FOUPs 308 are supported. The substrates are loaded into and unloaded from the loadlock chamber 310, the transfer chamber 302 housing a substrate handler 312, and a series of processing chambers 304a-304c. The loadlock chamber 310 may pump down the substrates introduced in the processing system 300 to maintain vacuum seal.

Each processing chamber 304a-304c may be outfitted to perform a number of substrate operations. For example, processing chamber 304a may be a chamber for directional modification of a substrate surface, such as a suitably adapted Sym3™ chamber; processing chamber 304b may be a deposition chamber for depositing an etchant, such as a suitably adapted Frontier™ chamber; and processing chamber 304c may be a high-temperature chamber for sublimation.

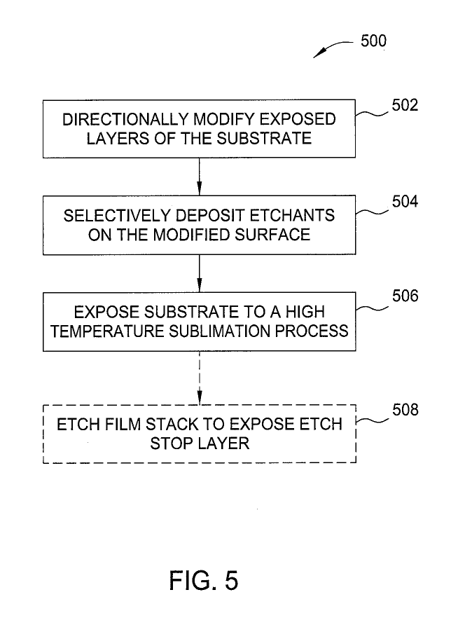

The controller 320 may be configured to operate all aspects of the processing system 300, such as the method discussed below in conjunction with FIG. 5. For example, the controller 320 may be configured to control the method of forming a metal interconnect on a substrate. The controller 320 includes a programmable central processing unit (CPU) 322 that is operable with a memory 324 and a mass storage device, an input control unit, and a display unit (not shown), such as power supplies, clocks, cache, input/output (I/O) circuits, and the liner, coupled to the various components of the processing system to facilitate control of the substrate processing. The controller 320 also includes hardware for monitoring substrate processing through sensors in the processing system 300, including sensors monitoring the precursor, process gas, and purge gas flow. Other sensors that measure system parameters, such as substrate temperature, chamber atmosphere pressure, and the like, may also provide information to the controller 320.

To facilitate control of the processing system 300 described above, the CPU 322 may be one of any form of general purpose computer processor that can be used in an industrial setting, such as a programmable logic controller (PLC), for controlling various chambers and sub-processors. The memory 324 is coupled to the CPU 322 and the memory 324 is non-transitory and may be one or more of readily available memory such as random access memory (RAM), read only memory (ROM), floppy disk drive, hard disk, or any other form of digital storage, local or remote. Support circuits 326 are coupled to the CPU 322 for supporting the processor in a conventional manner. Charged species generation, heating, and other processes are generally stored in the memory 324, typically as software routine. The software routine may also be stored and/or executed by a second CPU (not shown) that is remotely located from the hardware being controlled by the CPU 322.

The memory 324 is in the form of computer-readable storage media that contains instructions, that when executed by the CPU 322, facilitates the operation of the processing system 300. The instructions in the memory 324 are in the form of a program product such as a program that implements the method of the present disclosure. The program code may conform to any one of a number of different programming languages. In one example, the disclosure may be implemented as a program product stored on a computer-readable storage media for use with a computer system. The program(s) of the program product define functions of the embodiments (including the methods described herein). Illustrative computer-readable storage media include, but are not limited to: (i) non-writable storage media (e.g., read-only memory devices within a computer such as CD-ROM disks readable by a CD-ROM drive, flash memory, ROM chips, or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure.

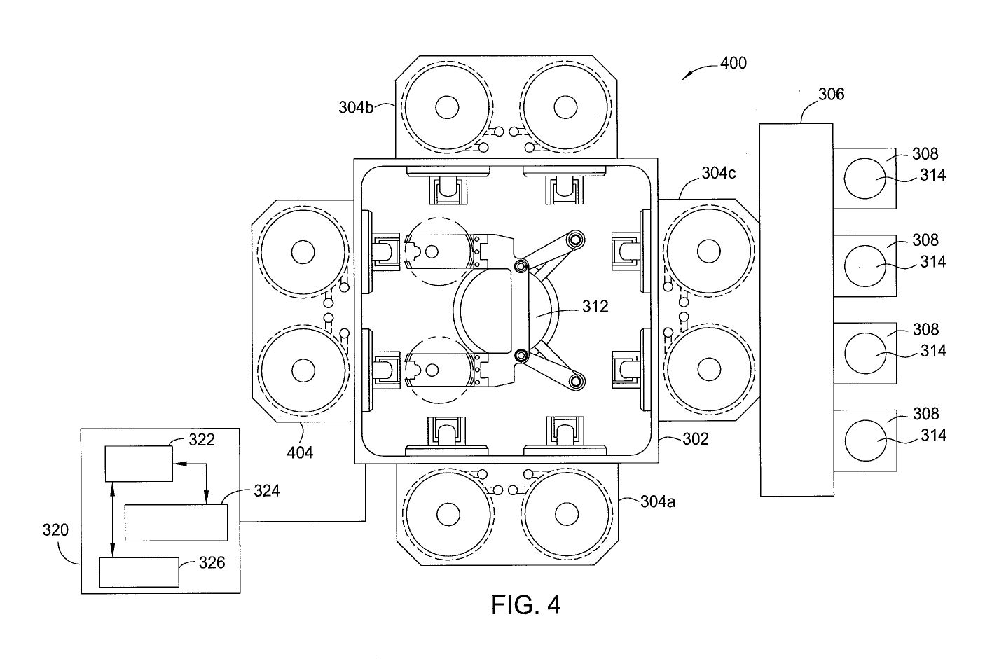

FIG. 4 illustrates a semiconductor processing system 400, according to one embodiment. The semiconductor processing system 400 is similar to semiconductor processing system 300. However, in semiconductor processing system 400, the high-temperature chamber 304c is moved to the loadlock chamber location (in FIG. 3). The semiconductor processing system 400 further includes chamber 404 coupled to the transfer chamber 302. In one example, chamber 404 may be a chemical vapor deposition (CVD) chamber.

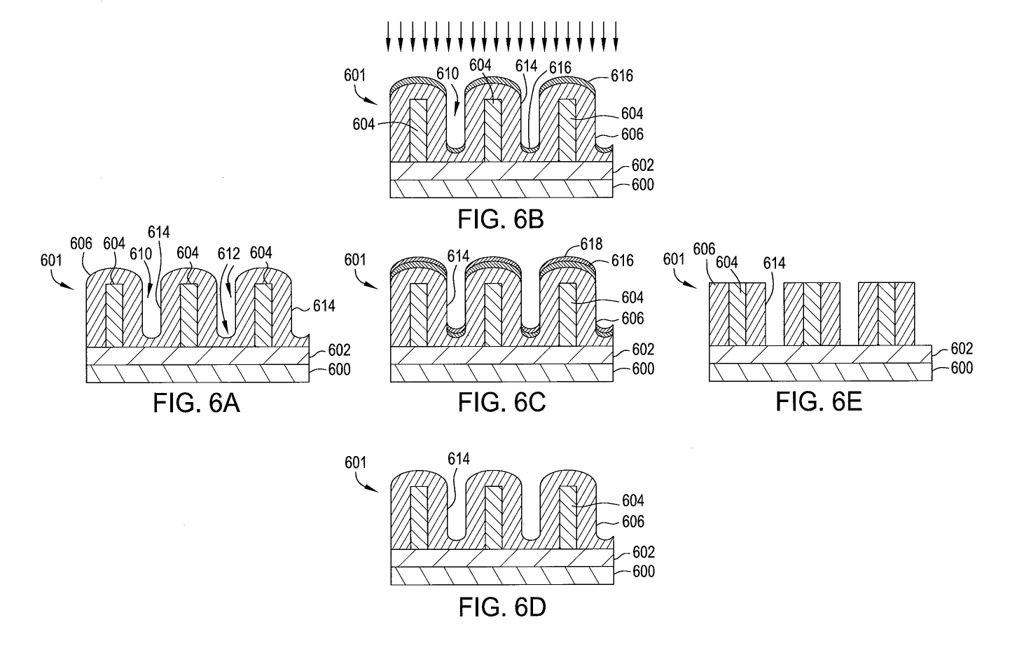

FIG. 5 is a flow diagram that illustrates one embodiment of a method 500 for processing a substrate. FIGS. 6A-E illustrate cross-sectional views of the substrate at different stages of the method 500 of FIG. 500.

FIG. 6A depicts a substrate 600. The substrate 600 has deposited thereon a film stack 601 comprising an etch stop layer 602, a patterned structure 604, and a spacer layer 606. The etch stop layer 602 is deposited on the surface of the substrate 600. The patterned structure 604 is deposited on the etch stop layer 602. A plurality of openings 610 are formed between the patterned structure 604. The plurality of openings 610 expose a portion 612 of the etch stop layer 602. The spacer layer 606 is deposited on sidewalls 614 of the patterned structure 604 and the exposed portions 612. The spacer layer 606 may be a dielectric material different from the materials selected for the etch stop layer 602.

The method 500 begins at block 502. At block 502, the exposed layers of the substrate 600 are directionally modified with an active chemistry based plasma, as shown in FIG. 6B. For example, the exposed layers are directionally modified with non-active plasma treatment 616. In one embodiment, the non-active plasma treatment may be performed in chamber 304a. Insert gases may be used to generate the non-active plasma treatment 616.

At block 504, etchants 618 are selectively deposited on the modified surface of the exposed layers, as shown in FIG. 6C. The etchants may be deposited with downstream plasma in a low-pressure/low-temperature environment, such as in chamber 304b.

At block 506, the substrate 600 is exposed to a high-temperature sublimation process, as shown in FIG. 6D. The high-temperature sublimation process may be performed in a high-temperature processing chamber, such as chamber 304c. The high-temperature sublimation process is configured to expose the patterned structure 604 by removing the etchants 618 deposited in block 504. Blocks 502-506 may be repeated until the patterned structure 604 is exposed.

In one embodiment, the method 500 further includes block 508. At block 508, the substrate 600 undergoes an etch process to expose the etch stop layer 602 in the openings 610, as shown in FIG. 6E. For example, the substrate 600 may be transferred to a CVD chamber, such as chamber 404 in FIG. 4. After transfer, the etch stop layer 602 in openings 610 is exposed through an etch process.

While the foregoing is directed to specific embodiments, other and further embodiments may be devised without departing from the basic scope thereof, and the scope thereof is determined by the claims that follow.

What is claimed is:

1. A processing system for processing a substrate, comprising:
a transfer chamber; and
a plurality of process chambers coupled to the transfer chamber, the plurality of process chambers comprising:
a first process chamber configured to directionally modify a surface of a film stack deposited on the substrate;
a second process chamber configured to deposit an etchant on the surface of film stack; and
a third process chamber configured to expose the film stack to a high-temperature sublimation process.

2. The processing system of claim 1, wherein the plurality of process chambers further comprises:
a fourth process chamber configured to etch the substrate.

3. The processing system of claim 1, wherein the first process chamber is configured to directionally modify the surface of the film stack with a non-reactive gas.

4. The processing system of claim 3, wherein first process chamber is coupled to a gas panel configured to provide the non-reactive gas in the form of H₂.

5. The processing system of claim 1, wherein the second process chamber is coupled to a gas panel configured to provide fluorine.

6. The processing system of claim 1, wherein the third process chamber comprises heaters operable to maintain a temperature of the third process chamber between about 80° C. and about 100° C.

7. The processing system of claim 6, wherein the third process chamber is raised to a pressure.

8. A method for processing a substrate comprising:
directionally modifying exposed layers of a film stack deposited on a surface of the substrate;
selectively depositing etchants on a modified surface of the exposed layers; and
exposing the substrate to a high-temperature sublimation process.

9. The method of claim 8, further comprising:
etching the film stack to expose an etch stop layer.

10. The method of claim 8, wherein directionally modifying exposed layers of the film stack deposited on a surface of the substrate comprises:
supplying a non-reactive gas.

11. The method of claim 11, wherein the non-reactive gas is in the form of H₂.

12. The method of claim 8, wherein selectively depositing etchants on a modified surface of the exposed layers comprises:
providing a fluorine-containing gas to the modified surface of the exposed layers.

13. The method of claim 8, wherein exposing the substrate to a high-temperature sublimation process comprises:
raising a temperature of a chamber in which the substrate is exposed to the high-temperature sublimation process.

14. The method of claim 8, wherein directionally modifying exposed layers of a film stack deposited on a surface of the substrate comprises:
reducing a pressure in a chamber in which the exposed layers of the film stack deposited on the surface of the substrate are directionally modified to about 5 mT.

15. A processing system for processing a substrate, comprising:
a transfer chamber;
a plurality of process chambers coupled to the transfer chamber, the plurality of process chambers comprising:
a first process chamber configured to directionally modify a surface of a film stack deposited on the substrate;
a second process chamber configured to deposit an etchant on the surface of film stack;
a third process chamber configured to expose the film stack to a high-temperature sublimation process; and
a fourth process chamber configured to etch the film stack; and
a substrate handler disposed in the transfer chamber and configured to transfer the substrate among the process chambers.

16. The processing system of claim 15, wherein the first process chamber is configured to directionally modify the surface of the film stack with a non-reactive gas.

17. The processing system of claim 16, wherein the first process chamber is coupled to a gas panel configured to provide the non-reactive gas in the form of H₂.

18. The processing system of claim 15, wherein the second process chamber is coupled to a gas panel and configured to provide fluorine.

19. The processing system of claim 15, wherein the third process chamber comprises heaters operable to maintain a temperature of the third processing chamber between 80° C. and 100° C.

20. The processing chamber of claim 19, wherein the third process chamber is raised to a pressure.
